(19) United States
(12) Patent Application Publication
(10) Pub. No.: US 2009/0301547 A1
(43) Pub. Date: Dec. 10, 2009

(54) SOLAR GENERATORS COMPRISING FLOATING HOLLOW ELEMENTS

(75) Inventors: Nikolaus Johannes Laing, Remseck (DE); Inge Laing, La Jolla, CA (US); Andreas Hesse, Wenden (DE)

Correspondence Address: FOLEY & LARDNER LLP, P.O. BOX 80278, SAN DIEGO, CA, 92138-0278, US

(73) Assignee: PYRON, INC.

(21) Appl. No.: 12/282,505

(22) PCT Filed: Mar. 9, 2007
(86) PCT No.: PCT/EP2007/002081

§ 371 Date: Jul. 24, 2009

Related U.S. Application Data
(60) Provisional application No. 60/795,666, filed on Apr. 27, 2006.

(30) Foreign Application Priority Data
Mar. 11, 2006 (DE) 10 2006 011 295.4

(51) Int. Cl. H01L 31/052; H01L 31/042

(52) U.S. Cl. 136/246; 136/244

(57) ABSTRACT

The present invention relates to a solar power generator having special solar radiation concentrators configured as hollow bodies, and to such concentrators themselves. The invention relates in particular to a solar power generator having modules, arranged on a water layer, that contain a radiation converter, such that a plurality of modules is respectively combined into floating hollow bodies that comprise a wall that is subdivided into light-transmitting and non-light-transmitting regions.

### TECHNICAL FIELD

The present invention relates to a solar power generator having special solar radiation concentrators configured as hollow bodies, and to such concentrators themselves.

### BACKGROUND OF THE INVENTION

Solar generators having photocells have been made known; in such generators, troughs lying next to one another, which carry concentrator apparatuses and photocells, float on a water layer. Reference may be made in this context, by way of example, to the two patent applications WO 03/034506 and WO 2006/027220, which disclose solar generator systems of this kind.

### DESCRIPTION OF THE INVENTION

The invention provides for the use, instead of the troughs, of elongated cylindrical hollow bodies that contain walls, embodied as concentrator lenses, that are directed toward the sun during operation. The remaining regions of the hollow bodies are advantageously made of plastic materials; as a result, the hollow bodies are very light.

In terms of statics, the hollow bodies constitute tubes that are closed at both axial ends. Because they are advantageously intended to be very long, a high level of flexural and torsional rigidity is necessary, which is not achievable with troughs made up of open trays. At the same time, the interior of such hollow bodies is separated from the ambient air, thereby avoiding fogging of the inwardly facing wall regions of the concentrator lenses.

Because the hollow bodies float, they can be made very long without suffering deformation. This accommodates installation in a floating ring, since the lengths of the hollow bodies increase, within a quadrant of the ring surrounding the hollow body, up to the ring's radial length.

In known fashion, the hollow bodies, together with the floating ring surrounding, them experience a pivoting from east to west at the azimuthal velocity of the Sun. They track the change in Sun height by pivoting about their longitudinal axes.

It is possible to design the hollow bodies to be pivotable through 180 degrees so that the concentrator lenses dip into the water layer, with the result that, for example, in the event of a sandstorm they are protected and simultaneously cleaned. Cleaning is intensified if the water is impinged upon by ultrasound.

What is optimal is a power plant in which, instead of one large platform surrounded by a ring, three smaller platforms are combined into one unit, with the result that the floating hollow bodies can be made so light that they can be replaced by one person.

The present invention therefore refers, in a first embodiment, to a solar power generator having modules, arranged on a water layer, that contain a radiation converter, a plurality of modules being respectively combined into floating hollow bodies that comprise a wall that is subdivided into light-transmitting and non-light-transmitting regions.

In a further embodiment, the invention refers to a solar power generator of this kind such that the light-transmitting wall regions are embodied as concentrator lenses.

In a further embodiment, the invention refers to a solar power generator of this kind such that the light-transmitting wall regions extend in curved fashion.

In a further embodiment, the invention refers to a solar power generator of this kind such that the light-transmitting wall regions have a fluted cross section.

In a further embodiment, the invention refers to a solar power generator of this kind such that the light-transmitting wall regions are spherically concave segments.

In a further embodiment, the invention refers to a solar power generator of this kind such that the surfaces of the light-transmitting wall regions have a reflection-decreasing nanostructure.

In a further embodiment, the invention refers to a solar power generator of this kind such that openings in the hollow bodies, the geometric axes of which intersect the focus of the concentrator lens, are arranged opposite the concentration lenses.

In a further embodiment, the invention refers to a solar power generator of this kind such that the hollow bodies float inside a floating ring, and are mounted pivotably about their longitudinal axis.

In a further embodiment, the invention refers to a solar power generator of this kind such that the floating ring is fabricated by extrusion.

In a further embodiment, the invention refers to a solar power generator of this kind such that the cross section of the floating ring is rectangular.

In a further embodiment, the invention refers to a solar power generator of this kind such that a roller chain that is joined fixedly to the floating ring extends on the periphery of the ring.

In a further embodiment, the invention refers to a solar power generator of this kind such that the floating ring is made of a plastic material.

In a further embodiment, the invention refers to a solar power generator of this kind such that fastening of the roller chain is accomplished via elongated chain pins arranged in regularly distributed fashion.

In a further embodiment, the invention refers to a solar power generator of this kind such that the ring is subdivided into circular arc segments whose ends receive short rectangular tubes.

In a further embodiment, the invention refers to a solar power generator of this kind having a hollow body, floating on a water layer, that is pivotable about its longitudinal axis, the region of its wall that penetrates into the water layer forming part of a circular cylinder.

In a further embodiment, the invention refers to a solar power generator of this kind such that the axis of the circular cylinder coincides with the longitudinal axis of the hollow body.

The invention moreover refers to the aforesaid hollow body as an isolated constituent or as part of the solar power generator, the hollow body comprising, depending on the embodiment, a special internal wiring layout as described below. The invention also refers, however, to the special internal wiring of the aforesaid hollow body itself.

In an embodiment, the invention refers to a wiring layout of this kind such that the negative pole of one energy converter is connected to the positive pole of the adjacent energy converter via an insulated lead that comprises in part semicircular regions, the ends of the semicircular region being joined to one another by a tension spring.

In a further embodiment, the invention refers to a wiring layout of this kind such that a lead is embedded into its plastic wall; and contact elements attached to the energy converter can be inserted into counter-contacts attached in the hollow body in the region of the openings.

In a further embodiment, the invention refers to a solar power generator of this kind such that the end regions of a hollow body are embodied so that they can be joined to the end regions of a further hollow body.

The invention additionally relates to a method for flange-mounting the energy converters onto a hollow body, the leads being pulled outward through the openings against the tensile force of the tension springs and being connected to the terminals of the energy converters before flange-mounting of the energy converter.

In a further embodiment, the invention relates to a solar power generator of this kind such that a portion of the walls of the hollow bodies is made of a material that allows moisture to pass outward, but not in the opposite direction.

In a further embodiment, the invention also encompasses concentrators, floating on a water layer, for the utilization of solar energy, which track the solar elevation by pivoting about their longitudinal axis, such that the pivoting is possible about an angle sufficiently large that the concentrator lens dips into the water layer.

In a further embodiment, the invention relates to a solar power generator of this kind such that the water layer is impinged upon by ultrasound.

In a further embodiment, the invention relates to a solar power generator of this kind, having a ring floating on a water layer, such that the ring is guided in a clamp element between wheels whose axes are oriented approximately vertically.

In a further embodiment, the invention relates to a solar power generator of this kind such that one of the wheels is driven by a motor that causes the ring to rotate.

In a further embodiment, the invention relates to a solar power generator of this kind such that three clamp elements hold three rings together; and the rings are held at a distance by a wheel engaging on the outer periphery of the rings.

In a further embodiment, the invention relates to a solar power generator of this kind such that multiple rollers, mounted in stationary fashion, roll on the inner periphery of the rings.

In a further embodiment, the invention relates to a solar power generator of this kind such that one wheel located between the rings is embodied as a wheel bearing teeth.

In a further embodiment, the invention relates to a solar power generator of this kind such that one wheel located between the rings is embodied as a chain wheel; and each of the rings is surrounded by a roller chain joined immovably to the ring, into which chain the chain wheel engages.

In a further embodiment, the invention relates to a solar power generator of this kind such that the buoyancy of a tube that floats in the water supports the clamp element.

In a further embodiment, the invention relates to a solar power generator of this kind such that three rings are combined into one unit; and in the regions in which two adjacent rings have the least spacing from one another, a clamp element designed for two rings holds the rings together.

In a further embodiment, the invention relates to a solar power generator of this kind having three rings that enclose between them a gusset space at whose center is located a column from which proceed three tubes, each of which carries a clamp element.

In a further embodiment, the invention relates to a solar power generator of this kind having a tube whose end is joined to a body that is heavier than water.

In a further embodiment, the invention relates to a solar power generator of this kind such that to prevent evaporation, the water layer carries a film of a chemical whose principal constituent is isobutylene.

In a further embodiment, the invention relates to a solar power generator of this kind such that the light-transmitting regions of the hollow bodies are made of glass that carries a plastic layer equipped with optical flutes.

In a further embodiment, the invention relates to a solar power generator of this kind such that the lower side of the floating ring and the lower side of the hollow bodies extend on one plane, so that rotation of a platform can take place even when the water layer is covered with ice.

In a further embodiment, the invention relates to a solar power generator of this kind such that the lens-forming wall regions are sprayed with water, taken from the water layer, that passes through a filter.

In a further embodiment, the invention relates to a solar power generator of this kind such that the concentrated radiation is utilized for direct water cleavage.

### DESCRIPTION OF THE FIGURES

The invention will be explained with reference to Figures.

FIG. 1 shows a hollow body closed on all sides.

FIG. 2a is a cross section through FIG. 1 in the noon position.

FIG. 2b is a cross section of the morning position.

FIG. 3 is a section through the energy converter.

FIG. 4 shows the wiring layout inside the hollow body.

FIG. 5 shows a platform having hollow bodies of different lengths.

FIG. 6a shows a connecting element for the floating ring.

FIG. 6b shows the connecting element in section.

FIG. 7a shows a power plant having three platforms and a central column.

FIG. 7b shows the kinematic parts of the clamp element.

FIG. 8 shows the construction of the drive apparatus in the clamp element.

FIG. 9 shows the booms between the platforms.

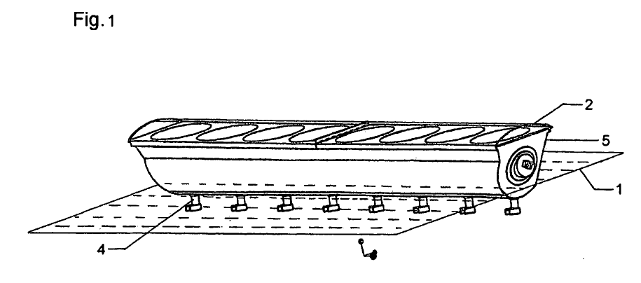

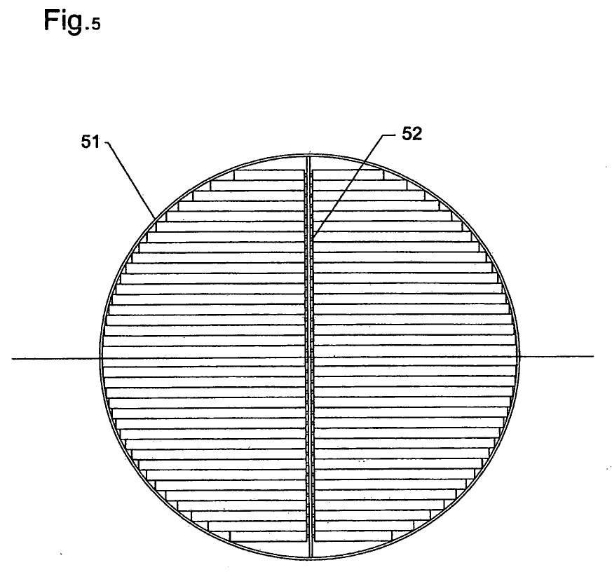

FIG. 1 shows, in schematic fashion, a hollow body on water surface 1. Transparent region 2 forming the lens is part of a cylinder, but can also be embodied in fluted fashion or as a flat plate. Located in the lower region of the hollow body are openings through which energy converters 4 project into the interior. Located at the ends of the hollow bodies are end plates on which stub shafts 5 are fastened. It is useful if pre-tensioned cables, made for example from glass fiber or carbon fiber, extend between the end plates; said cables can be laminated into the wall, with the result that the permissible length of the hollow bodies is increased. Hollow-body lengths that correspond to the spacing between partition 52 and ring 51 in FIG. 5 are desirable. The end plates of the hollow bodies are embodied so that hollow bodies can be extended by one or more module units by fastening further hollow bodies to the primary hollow body.

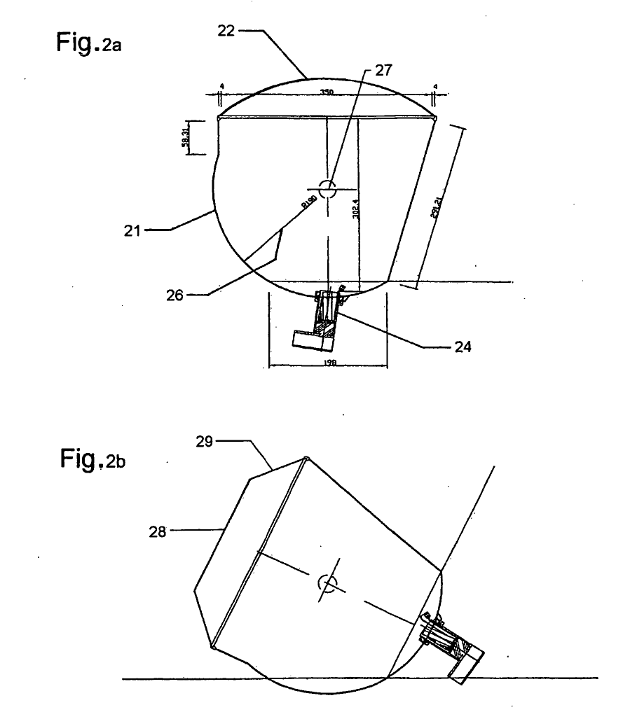

FIG. 2a shows water surface 1 and the hollow body in the noon position. Surface regions 21 extend along a circular cylinder whose axis 27 passes through the center of gravity. The result is that with the hollow body in any oblique position, said axis has the same spacing 26 from the cylindrical portion of wall 21. The wall regions are preferably made of plastic material reinforced with glass fiber or carbon fiber. In the upper region, wall 21 transitions into a transparent region that is embodied as a concentrator lens 22. This region can be embodied as a planar or cylindrical body but also in fluted fashion. The regions dipping into the water are dimensioned so that the buoyancy generated corresponds to the weight of the hollow body. The hollow bodies comprise openings through which the externally located energy converters 24 extend into the interior of the hollow body. The current that is generated is directed through insulated leads by which adjacent energy converters 24 are connected to one another, thus enabling series connection and group connection.

FIG. 2b shows the same hollow body in the morning position. The concentrating region of the hollow bodies can also be made of glass that is covered with a plastic layer which carries the optical fluting. It is furthermore advantageous if the concentrating wall carries a nanostructure in order to decrease scattering losses.

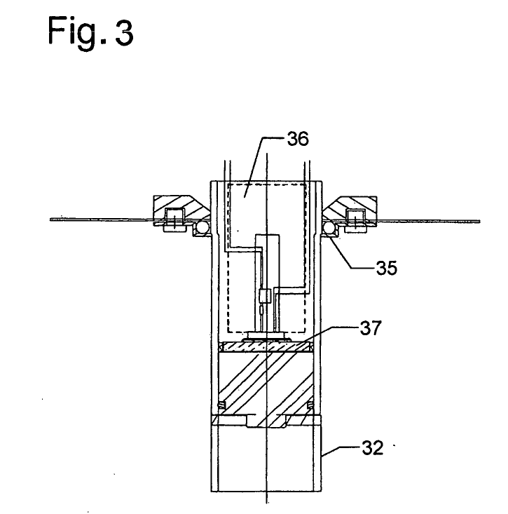

FIG. 3 is a section through an energy converter. The housing comprises a tubular piece 34 that is joined to flange 35. Secondary optical system 36, which uniformly distributes onto the photocell the rays striking said system in the focal region, is visible. Region 37 receiving the photocells dips into body of water 31, which results in extremely good cell cooling. This is followed by a region 32 that projects into the water even with the hollow body in the extremely oblique position early in the morning. In order to impede water penetration, which is unavoidable over the long term, a window can be provided which allows water to pass through outward but prevents the inward penetration of water.

In order to increase heat transfer in standing water, the invention provides for having the water impinged upon by acoustic waves. Ultrasound is suitable in order to enhance cleaning of the concentrator lenses.

To ensure that current can be generated even below freezing, provision is made that the floating ring and the support surface of the hollow bodies extend on one plane. It is thereby possible to move the elements on a sheet of ice.

The invention also provides for using, instead of photovoltaic energy converters, chemical converters which make it possible to utilize irradiation energy for water cleavage.

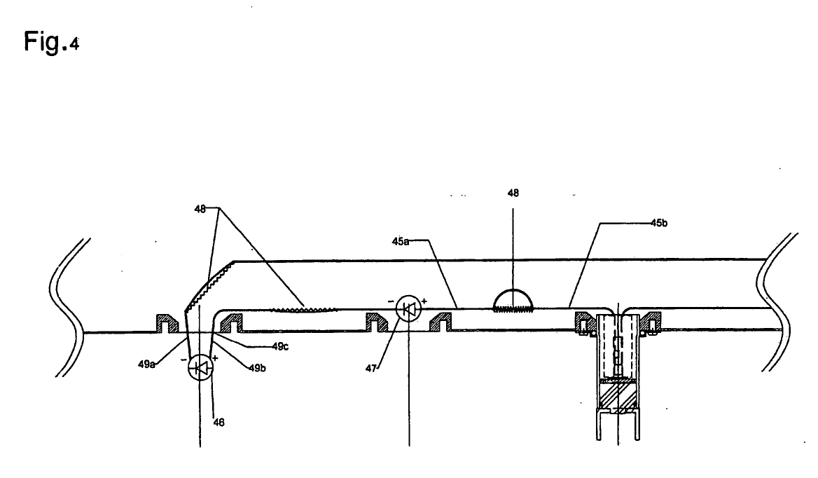

FIG. 4 shows the wiring layouts in the interior of the hollow body. The positive lead of the left energy converter 46 is connected to the negative lead of the neighboring energy converter 47, while the negative lead of energy converter 46 proceeds to the end of the series circuit. In a region between two energy converters, for example 46 and 47, the leads extend along semicircles 40 on whose diameter a helical tension spring 48 is joined to leads 45a and 45b. Tension spring 48 makes it possible for the connector ends of leads 49a and 49b to be pulled through opening 49c upon installation of the energy converter, so that energy converter 46 can be electrically connected outside the hollow body before energy converter 46 is bolted onto the hollow body. Tension spring 48 then brings the leads back into the initial position.

FIG. 5 is a plan view of floating ring 51 in which hollow bodies 54, proceeding parallel to one another, are mounted pivotably about the horizontally extending longitudinal axis of the hollow bodies.

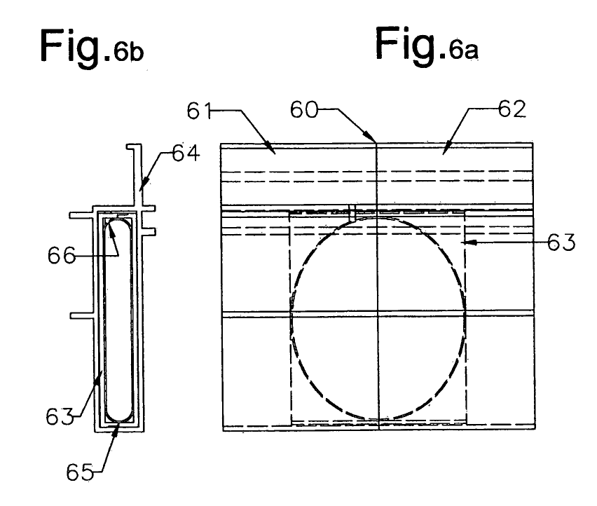

FIG. 6a schematically shows abutting points 60 between circle segments 61 and 62 of the floating ring, which is assembled from circle segments. Connection at an abutting point 60 is accomplished by way of a rectangular tube 63, assembled from two identical parts, that is adhesively bonded to the inner walls of the hollow ring.

FIG. 6b shows a cross section 64 through the ring. Rectangular tube 63 is adhesively bonded in the interior of the circle segments that butt against one another. Placed inside rectangular tube 63 is a bladder 65, made of a rubber material, that has a filling opening 66. After circle segments 61 and 62 are pushed together, bladder 65 is filled with compressed air. It then presses the wall elements of rectangular tube 63 against the inner walls of circle segments 61 and 62.

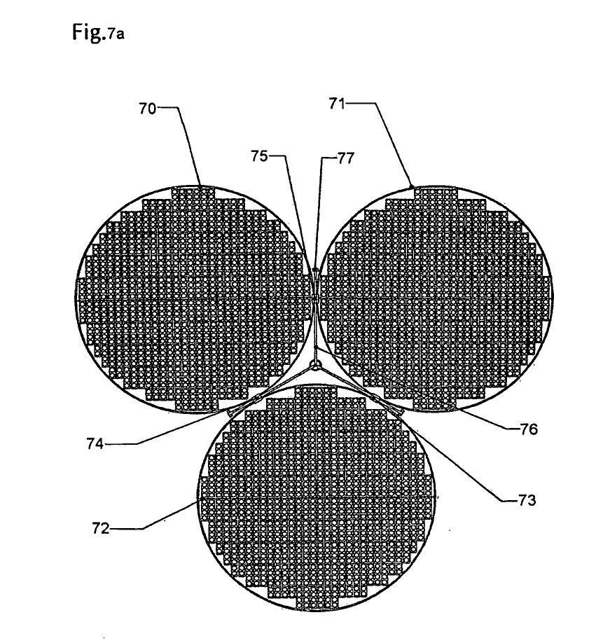

FIG. 7a shows an arrangement in which three platforms 70, 71, 72 are combined into a triad. Clamp elements 73, 74, and 75 are arranged at the respective contact regions. Said elements are supported by the buoyancy of tube 76. Located at the end of each of said tubes is a concrete weight 77 for immobilization on the bottom of the water layer, which is constituted by a thermoplastic film that, at the edges of the water layer, extends over a fill.

FIG. 7b is a plan view of a clamp element that holds the two adjacent floating rings 71a and 73a together by clamping around them, and at the same time transfers the rotary motion of geared motor 72 via chain wheel 74 to the two floating rings 71a and 73a. Rollers 76 prevent these rings from migrating out in a radial direction as long as the rings are held in a horizontal position by the body of water. In the case of a triad, a third ring is joined to the two rings via two further (but motorless) clamp elements.

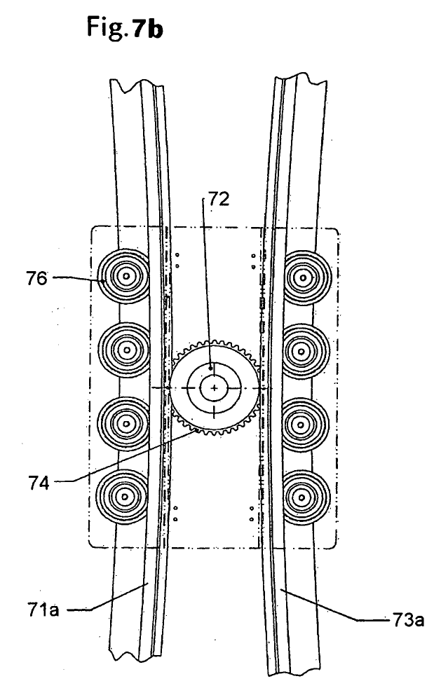

FIG. 8 shows, in vertical section, a clamp element between the rings of two platforms according to FIG. 7b. Chain wheel 71 is driven by geared motor 72 and transfers torque to the portion of the floating rings constituted by roller chains. Floating rings 71b and 73b are embraced by chain wheel 74 and by rollers 76 in such a way that complete connection of the rings lying in a horizontal position in body of water 70 is produced. Chain wheel 74 transfers force to two roller chains 78 and 79, which are held by elongated chain bolts 79b in a channel of the rings. Extending beneath the apparatus is a hollow rectangular tube 77 whose buoyancy supports the apparatus.

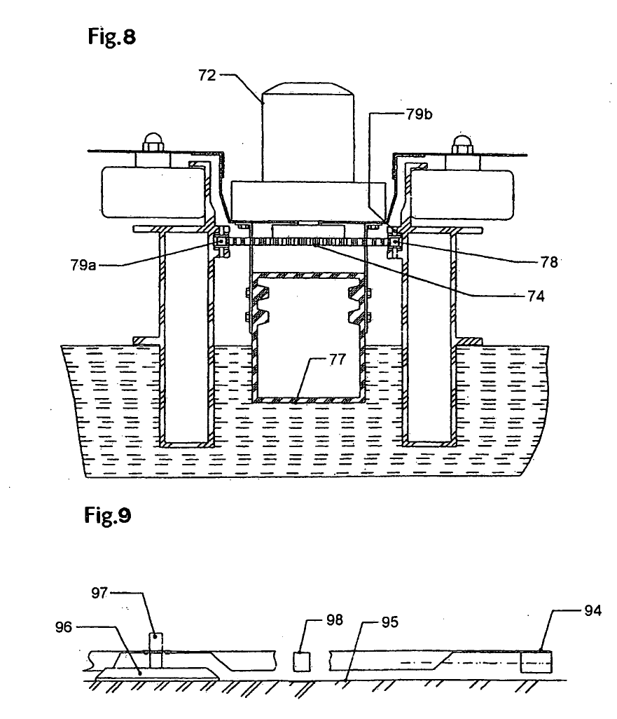

FIG. 9 shows a floating tube 98. Tube 98 is connected, in the central region between three platforms, to a plate 90. In the gusset region, the tube is joined to column 97 at the center. This column 97 is installed on a heavy circular disk 96 that rests on a thermoplastic film 95 but is displaceable on said film to the final location. At the end of the tube, the latter is joined to a concrete weight 94 that prevents the tube from lifting up and migrating out. The tube dips as far as waterline 92 into the body of water, which is separated from the ground by a plastic film.

1. A solar power generator having modules, arranged on a water layer, that contain a radiation converter, wherein a plurality of modules is respectively combined into floating hollow bodies that comprise a wall that is subdivided into light-transmitting and non-light-transmitting regions.

2. The solar power generator according to claim 1, wherein the light-transmitting wall regions are embodied as concentrator lenses.

3. The solar power generator according to claim 2, wherein the light-transmitting wall regions extend in curved fashion.

4. The solar power generator according to claim 2, wherein the light-transmitting wall regions have a fluted cross section.

5. The solar power generator according to claim 2, wherein the light-transmitting wall regions are spherically concave segments.

6. The solar power generator according to claim 1, wherein the surfaces of the light-transmitting wall regions have a reflection-decreasing nanostructure.

7. The solar power generator according to claim 2, wherein openings in the hollow bodies, the geometric axes of which intersect the focus of the concentrator lens, are arranged opposite the concentration lenses.

8. The solar power generator according to claim 1, wherein the hollow bodies float inside a floating ring, and are mounted pivotably about their longitudinal axis.

9. The solar power generator according to claim 8, wherein the floating ring is fabricated by extrusion.

10. The solar power generator according to claim 8, wherein the cross section of the floating ring is rectangular.

11. The solar power generator according to claim 2, wherein a roller chain that is joined fixedly to the floating ring extends on the periphery of the ring.

12. The solar power generator according to claim 10, wherein the floating ring is made of a plastic material.

13. The solar power generator according to claim 8, wherein fastening of the roller chain is accomplished via elongated chain pins arranged in regularly distributed fashion.

14. The solar power generator according to claim 8, wherein the ring is subdivided into circular arc segments whose ends receive short rectangular tubes.

15. The solar power generator having a hollow body according to claim 2, floating on a water layer, that is pivotable about its longitudinal axis, wherein the region of its wall that penetrates into the water layer forms part of a circular cylinder.

16. The solar power generator according to claim 15, wherein the axis of the circular cylinder coincides with the longitudinal axis of the hollow body.

17. A wiring layout of the hollow body according to claim 1, wherein the negative pole of one energy converter is connected to the positive pole of the adjacent energy converter via an insulated lead that comprises in part semicircular regions, the ends of the semicircular region being joined to one another by a tension spring.

18. A wiring layout of the hollow body according to claim 1, wherein a lead is embedded into its plastic wall; and contact elements attached to the energy converter can be inserted into counter-contacts attached to the hollow body in the region of the openings.

19. The solar power generator according to claim 2, wherein the end regions of a hollow body are embodied so that they can be joined to the end regions of a further hollow body.

20. A method for flange-mounting the energy converters onto a hollow body according to claim 17, wherein the leads are pulled outward through the openings against the tensile force of the tension springs, and are connected to the terminals of the energy converters before flange-mounting of the energy converter.

21. The solar power generator according to claim 1, wherein a portion of the walls of the hollow bodies is made of a material that allows moisture to pass outward, but not in the opposite direction.

22. Concentrators, floating on a water layer, for the utilization of solar energy, which track the solar elevation by pivoting about their longitudinal axis, wherein the pivoting is possible about an angle sufficiently large that the concentrator lens dips into the water layer.

23. The solar power generator according to claim 8, wherein the water layer is impinged upon by ultrasound.

24. A solar power generator having a ring according to claim 8 floating on a water layer, wherein the ring is guided in a clamp element between wheels whose axes are oriented approximately vertically.

25. The solar power generator according to claim 24, wherein one of the wheels is driven by a motor that causes the ring to rotate.

26. The solar power generator according to claim 24, wherein three clamp elements hold three rings together; and the rings are held at a distance by a wheel engaging on the outer periphery of the rings.

27. The solar power generator according to claim 26, wherein multiple rollers, mounted in stationary fashion, roll on the inner periphery of the rings.

28. The solar power generator according to claim 26, wherein one wheel located between the rings is embodied as a wheel bearing teeth.

29. The solar power generator according to claim 28, wherein one wheel located between the rings is embodied as a chain wheel; and each of the rings is surrounded by a roller chain joined immovably to the ring, into which chain the chain wheel engages.

30. The solar power generator according to claim 26, wherein the buoyancy of a tube that floats in the water supports the clamp element.

31. The solar power generator according to claim 26, wherein three rings are combined into one unit; and in the regions in which two adjacent rings have the least spacing from one another, a clamp element designed for two rings holds the rings together.

32. The solar power generator according to claim 31, having three rings that enclose between them a gusset space at whose center is located a column from which proceed three tubes, each of which carries a clamp element.

33. The solar power generator having a tube according to claim 30 whose end is joined to a body that is heavier than water.

34. The solar power generator according to claim 1, wherein to prevent evaporation, the water layer carries a film of a chemical whose principal constituent is isobutylene.

35. The solar power generator according to claim 1, wherein the light-transmitting regions of the hollow bodies are made of glass that carries a plastic layer equipped with optical flutes.

36. The solar power generator according to claim 1, wherein the lower side of the floating ring and the lower side of the hollow bodies extend on one plane, so that rotation of a platform can take place even when the water layer is covered with ice.

37. The solar power generator according to claim 1, wherein the lens-forming wall regions are sprayed with water, taken from the water layer, that passes through a filter.

38. The solar power generator according to claim 1, wherein the concentrated radiation is utilized for direct water cleavage.
